(19) United States
(12) Patent Application Publication
(10) Pub. No.: US 2008/0092375 A1
(43) Pub. Date: Apr. 24, 2008

(54) Component Placement Apparatus

(75) Inventors: Josephus Martinus Maria Van Gastel, Tilburg (NL); Paul Alexander Humphrey Goede, Best (NL); Paulus Peter Hendricus Verstegen, Uden (NL); Henricus Martinus Johanna Maria Van Logten, Waalre (NL)

Correspondence Address: FOLEY AND LARDNER LLP;SUITE 500, 3000 K STREET NW, WASHINGTON, DC, 20007, US

(73) Assignee: Assembleon N.V., La Veldhoven (NL)

(21) Appl. No.: 11/572,897

(22) PCT Filed: Jun. 9, 2005
(86) PCT No.: PCT/NL05/00415

§ 371 Date: Jul. 17, 2007

(30) Foreign Application Priority Data
Jul. 30, 2004 (EP) 04103674.0

(51) Int. Cl. H05K 13/04

(52) U.S. Cl. 29/740; 29/739; 29/832

(57) ABSTRACT

Component placement apparatus (1, 31) comprising a storage device (2, 32) for storing components, means (3, 33) for transporting a component from the storage device (2, 32) to a transfer device (4, 5, 37) comprising at least one component pickup position, and a component pick and place device (6, 36) for picking up a component from the pickup position and placing the component on a desired location on a substrate (7) positioned on a substrate support. The transfer device (4, 5, 37) is movable between a position relatively close to the stationary storage device (2, 32) and a variable desired position above the substrate support relatively close to the movable pick and place device.

The invention relates to a component placement apparatus comprising a storage device for storing components, means for transporting a component from the storage device to a transfer device comprising at least one component pickup position, and a component pick and place device for picking up a component from the pickup position and placing the component on a desired location on a substrate positioned on a substrate support.

Such a component placement device is known from U.S. Pat. No. 5,649,356. The component placement apparatus according to this U.S. patent comprises a rotatable transfer device by means of which a component from the storage device is being picked up and being presented at a pickup position. From the pickup position a component is being picked up by means of the component pick and place device and placed on a desired location on the substrate.

The storage device, the transfer device as well as the component pick and place device constitute one single unit, which is movable above the substrate support and the substrate positioned thereon.

With such a component placement device the time necessary for picking up a component by means of the component pick and place device and placing the component on the desired location on the substrate is relatively short since the pickup position can be brought relatively close to the desired location on the substrate on which the component needs to be placed. However, since the storage device, the transfer device and the component pick and place device are being moved as one single unit above the substrate, this unit is relatively bulky and the accuracy by means of which said unit can be positioned above the desired location on the substrate will be relatively poor. By moving the storage device the components will hit each other and might get damaged. Furthermore, refill of the moving storage device is dangerous, so that refill only can take place if the whole unit comprising the storage device is brought to a standstill. This has the disadvantage that during the standstill no components can be placed on the substrate.

It is an object of the invention to provide a component placement apparatus by means of which the time necessary for picking and placing a component by means of the component pick and place device is relatively small whereas the accuracy by means of which the component can be placed on a desired location on the substrate is relatively high.

This object has been achieved by the component placement apparatus according to the invention in that the transfer device is movable between a position relatively close to the stationary storage device and a variable desired position above the substrate support relatively close to the movable pick and place device.

Since the transfer device and the pick and place device are being moved independently of each other, the accuracy by means of which the pick and place can be positioned above the substrate is relatively high. Since the component which needs to be placed on the substrate is being transported by means of the transfer device from the stationary storage device to the movable pick and place device the time necessary for the pick and place device to travel between the pick and place locations is relatively small. Another advantage of the component placement apparatus according to the invention is that the stationary storage device renders the maintenance and replenishing the storage device relatively easy.

An embodiment of the component placement apparatus according to the invention is characterized in that the transfer device comprises several component pickup positions for presenting several components at the same time.

By positioning on the transfer device several components, which need to be placed subsequently on the substrate by means of the pick and place device, the number of movements of the transfer device between the stationary storage device and the movable pick and place device is relatively small. Furthermore the overall time for placing the several components by means of the pick and place device on the substrate is further reduced.

Another embodiment of the component placement apparatus according to the invention is characterized in that the component placement apparatus comprising at least two transfer devices, whereby alternately one transfer device is being located near the storage device whilst the other transfer device is being located near the pick and place device.

In this manner one transfer device can be provided with components stored in the storage device whilst simultaneously components present on the other transfer device can be picked up by means of the pick and place device and being placed on the desired location on the substrate. In this manner it is possible to place continuously components by means of the component pick and place device without a loss of time necessary to refill the transfer device.

A further embodiment of the component placement apparatus according to the invention is characterized in that the transfer devices are movable along different sides of a guiding element extending above the substrate support.

By means of such a guiding element it is possible to move the transfer devices independently from each other, whereby it is also possible to position both the transfer devices near the storage device or near the pick and place device, if necessary.

Another embodiment of the component placement apparatus according to the invention is characterized in that the component placement apparatus comprises an exchange device for transporting the transfer devices above each other from a first side of the exchange device near the storage device to a second side of the exchange device remote from the storage device.

With such an exchange device it is possible to use relatively large transfer devices, which may extend over the total width of the substrate on which components by means of the component pick and place device needs to be placed. By transporting the transfer devices above each other, no interference of the two transfer devices will occur.

Yet another embodiment of the component placement apparatus according to the invention is characterized in that the means for transporting a component from the storage device to a transfer device comprise a further pick and place device for picking up at least one component from the storage device and placing the component on the transfer device on a component pickup position.

By means of said further pick and place device it is relatively easy to transport a component or several components from the storage device to the transfer device. In case that the pick and place device comprises several nozzles for picking up simultaneously a number of components from the storage device, it is possible to place several components simultaneously on the transfer device. The accuracy of said further pick and place device might be relatively low since the accuracy of the placed component depends mainly on the accuracy of the pick and place device by means of which the component is placed on the substrate.

Another embodiment of the component placement apparatus according to the invention is characterized in that the component pickup position is located on a level above the substrate and the support on which the substrate is being positioned.

In this manner it is possible to position the component pickup position above the substrate relatively close to the location on which the component must be placed. In the space between the level on which the component is picked up and the level on which the component is placed a camera can be inserted to determine the position of the component with respect to the pick and place device.

The invention will now further be explained with reference to the drawings in which:

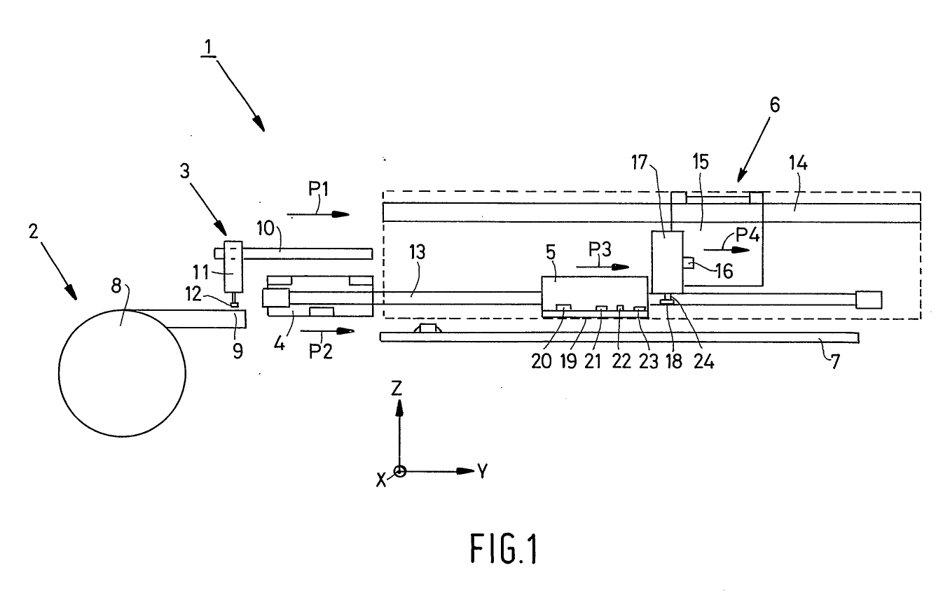

FIG. 1 is a side view of a first embodiment of a component placement apparatus according to the invention,

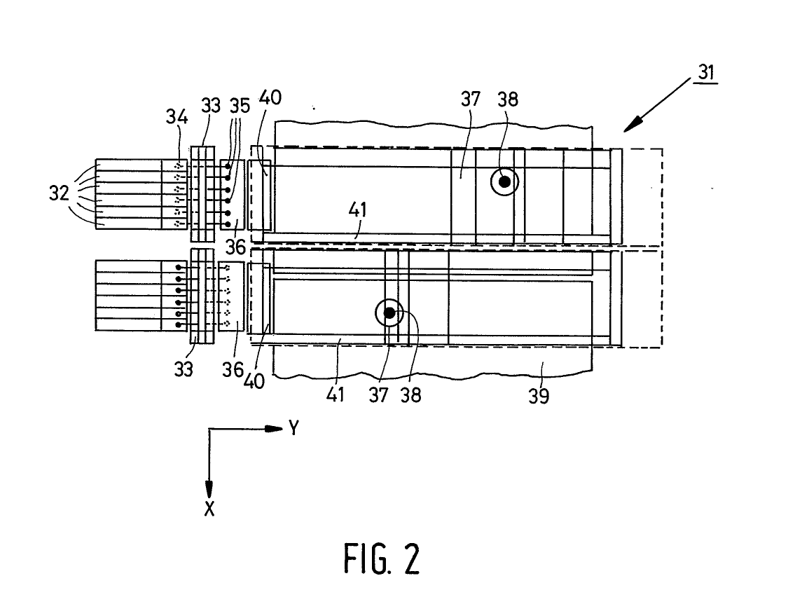

FIG. 2 is a top view of a second embodiment of a component placement apparatus according to the invention.

Like parts are numbered alike in the figures.

FIG. 1 shows a side view of a first embodiment of a component placement apparatus 1 according to the invention. The apparatus 1 comprises a storage device 2, a first pick and place device 3, transfer devices 4, 5, a second pick and place device 6 and a substrate support (not shown) on which a substrate 7 is being positioned.

The storage device 2 comprises a reel 8 on which a tape is being stored. Said tape comprises compartments in which components are being located. Such a reel and tape are well known in the prior art and will therefore not be further described. By means of the storage device 2 one component at a time will be presented at a component pickup position 9. The first pick and place device 3 comprises a guide 10 extending in the Y-direction along which a nozzle 11 is movable in and opposite to a direction indicated by P1. By means of the nozzle a component 12 present at the pickup position 9 can be picked up and placed on one of the transfer devices 4, 5. The transfer devices 4, 5 are each slidably connected to a guiding element 13 extending in the Y-direction. The transfer devices 4, 5 are each independently movable in and opposite to the directions indicated by arrows P2, P3. The transfer devices 4, 5 are located on a level above the level of the substrate 7. The guiding elements 13 extend above both sides of the area of the substrate 7 on which components need to be placed.

The second pick and place device 6 comprises a guide 14 extending in the Y-direction, along which a carriage 15 is movable in and opposite to a direction indicated by arrow P4. The guide 14 extends between the two guiding elements 13. The carriage 15 comprises a guide 16 extending in the X-direction along which a nozzle 17 is movable. By means of the nozzle 17 a component 18 can be picked up from one of the transfer devices 4, 5 and placed on the substrate 7.

Preferably the component placement apparatus 1 comprises a number of storage devices 2 located next to each other whereby the component pickup positions 9 are located on a line extending in the X-direction.

The operation of the component placement apparatus 1 according to the invention will now further be explained. By means of a controller one of the transfer devices 4, 5 is being displaced to a position close to the storage devices 2. In case that near each storage device 2 a component pick and place device 3 is located, it is possible to pick up a number of components by means of the component pick and place devices 3 and place them simultaneously on a platform 19 of the transfer devices 4, 5. The components 20-23 can be positioned on the platform 19 in a line extending in the X-direction or can be placed at random on said platform 19 depending on how many components need to be transferred simultaneously from the storage devices 2 to the pick and place devices 6. If the nozzle 11 is only movable in and opposite to a direction indicated by arrow P1, components from a first set of storage devices 2 will be placed on the transfer device 4 whilst components from a second set of storage devices 2 will be placed on the transfer device 5. However, in case that the nozzle 11 is also movable in and opposite to the X-direction it is possible to place components from all storage devices 2 on both transfer devices 4, 5.

As soon as the correct number and kind of component 20-23 are placed on the transfer device 4, 5, said transfer device is being moved in a direction indicated by arrow P2, P3 to a position close to the nozzle 17, after which by means of the nozzle 17 the components 20-23 are being picked up and being placed on the desired locations on the substrate 7. Hereto the nozzle 17 is being displaced both in the Y-direction as well as the X-direction. Furthermore the nozzle 17 comprises a tube 24, which is movable in the Z-direction from a relatively high level on which the components 20-23 are being located to a relatively low level on which the surface of the substrate 7 is located. Whilst the components 20-23 of the transfer device 5 are being picked up by means of the nozzle 17, components 12 are being picked up by means of one or more pick and place devices 3 from the storage devices 2 and are being placed on the other transfer device 4 which is located near the storage devices 2. As soon as the transfer device 4 comprises the right number and kind of components it is being displaced in the direction indicated by arrow P2 to the nozzle 17. Preferably the transfer device 4 is located near the nozzle 17 well before the transfer device 5 is being emptied so that an uninterrupted placement of the components by means of the nozzle 17 can be guaranteed. The now emptied transfer device 5 is then moved in a direction opposite to arrow P3 to a position close to the storage devices 2 so that new components 12 can be placed on the transfer device 5.

FIG. 2 shows a top view of a second embodiment of a component placement apparatus 31 according to the invention comprising a number of sets of six storage devices 32 (two of which are shown), a number of sets of pick and place devices 33, whereby by means of each set simultaneously six components can be picked up from the pickup positions 34 and be placed on positions 35 on a transfer device 36. The component placement apparatus 31 furthermore comprises a number of further transfer devices 37 on each of which also a row of six components can be placed.

The components apparatus 31 also comprises a number of pick and place devices 38 for placing components on a desired position on a substrate 39. The pick and place devices 38 are being movable in the same manner as the pick and place device 6 of the components placement apparatus as shown in FIG. 1.

The component placement apparatus 31 furthermore comprises a number of exchange devices 40 by means of which a transfer device 36 located near the storage devices 32 can be moved to the other side of the exchanged device 40 and vice versa whilst simultaneously the other transfer device 37 can be moved to a side of the exchange device close to the storage device. Preferably the transfer devices are being moved over each other.

The transfer device 37 which is located on the same side of the exchange device 40 as the component pick and place device 38 is being moved along a guide 41 to a position close to the pick and place device 38 and close to the positions on which the components need to be placed on the substrate 39.

As can be seen in FIG. 2 one of the pick and place devices 38 as well as the transfer device 37 are being located further away from the stationary storage devices 32 than the other pick and place device 38.

By means of a computer programme an optimalization can be calculated for placing the storage devices 32 and the movement of the pick and place devices 38 so that in a time as short as possible a maximum amount of components can be placed with a relatively high accuracy on a substrate 39.

The transfer device and the pick and place device might be moving towards each other to further reduce the time necessary for the pick and place device to pick up a component and place it on the substrate.

It is also possible to use trays, sticks, bulk feeders as storage devices.

It is possible to use a pick and place device for each storage device, whereby the pick and place device has a fixed or variable stroke in the Y-direction.

However, it is also possible to use one pick and place device for several storage devices, whereby the pick and place device is movable in the Y-direction as well as the X-direction.

It is also possible to move the transfer device not only in the Y-direction but also in the X-direction.

It is also possible to mount storage devices on the right side (FIG. 1) of the component placement apparatus as well, whereby one transfer device obtains components from storage devices located on the left side of the component placement device whilst the other transfer device obtains components from storage devices located on the right side.

1. Component placement apparatus comprising :
a storage device for storing components;
a transporting mechanism to transport a component from the storage device to a transfer device comprising at least one component pickup position; and
a component pick and place device for picking up a component from the pickup position and placing the component on a desired location on a substrate positioned on a substrate support,
wherein the transfer device is movable between a position close to the stationary storage device and a variable desired position above the substrate support close to the movable pick and place device.

2. Component placement apparatus according to claim 1, wherein the transfer device comprises a plurality of component pickup positions for presenting several components at the same time.

3. Component placement apparatus according to claim 1, wherein the component placement apparatus comprises at least two transfer devices, whereby alternately one transfer device is located near the storage device while the other transfer device is located near the pick and place device.

4. Component placement apparatus according to claim 3, wherein the transfer devices are movable along at least one guiding element extending above the substrate support.

5. Component placement apparatus according to claim 3, wherein the component placement apparatus comprises an exchange device for transporting the transfer devices above each other from a first side of the exchange device near the storage device to a second side of the exchange device remote from the storage device.

6. Component placement apparatus (1, 31) according to claim 1, wherein the transporting mechanism comprises a further pick and place device for picking up at least one component from the storage device and placing the component on the transfer device on a component pickup position.

7. Component placement apparatus according to claim 1, wherein the component pickup position is positioned on a level above the substrate and the support on which the substrate is positioned.
